(19) United States
(12) Patent Application Publication
(10) Pub. No.: US 2025/0379028 A1
(43) Pub. Date: Dec. 11, 2025

(54) DETECTING AND ADJUSTING LAMELLA DEFORMATION

(71) Applicant: FEI COMPANY, Hillsboro, OR (US)

(72) Inventors: Remco Geurts, Nuenen (NL); Pavel Potocek, Eindhoven (NL)

(21) Appl. No.: 18/734,069

(22) Filed: Jun. 5, 2024

(51) Int. Cl. H01J 37/305; H01J 37/304

(52) U.S. Cl. CPC H01J 37/3056; H01J 37/3045; H01J 2237/221; H01J 2237/24578; H01J 2237/24592; H01J 2237/2482; H01J 2237/3174; H01J 2237/31749

(57) ABSTRACT

A method including performing, with a charged particle system having a first milling setting, a first milling operation on a sample at a first time, generating a first image of the sample based on the first milling operation, determining, based on the first image, a first set of tracking features of the sample, performing, with the charged particle system having the first milling setting, a second milling operation on the sample at a second time, generating a second image of the sample based on the second milling operation, determining, based on the second image, a first change to the first set of tracking features, and adjusting the first milling setting to a second milling setting based on the first change.

### BACKGROUND

Charged particle systems are used in a variety of applications including the manufacture, repair, and inspection of miniature devices, such as integrated circuits, magnetic recording heads, and photolithography masks. One type of charged particle system may include a dual-beam microscope having a focused ion beam column and an electron microscope. To view samples with a dual-beam microscope, thin lamellae are formed from the sample including various structures and other features to be imaged with the dual-beam microscope. Lamellae are thin membranes that are partially transparent to electrons and are typically between 7 nm to 25 nm in thickness. Due to the small dimensions of the lamellae, careful preparation of the lamellae is required to preserve structures in the sample for imaging.

### BRIEF SUMMARY

One aspect of the disclosure provides for a method including performing, with a charged particle system having a first milling setting, a first milling operation on a sample at a first time. The method also includes generating a first image of the sample based on the first milling operation. The method also includes determining, based on the first image, a first set of tracking features of the sample. The method also includes performing, with the charged particle system having the first milling setting, a second milling operation on the sample at a second time. The method also includes generating a second image of the sample based on the second milling operation. The method also includes determining, based on the second image, a first change to the first set of tracking features. The method also includes adjusting the first milling setting to a second milling setting based on the first change.

Implementations may include one or more of the following features. The method where: determining the first set of tracking features includes determining a first attribute of the first set of tracking features; determining the first change includes determining a first attribute change to the first attribute; and adjusting the first milling setting includes adjusting the first milling setting based on the first attribute change. The method may further comprise: determining that a capping layer of the sample is milled too thin based on the first attribute change; and adjusting the first milling setting based on the determination that the capping layer is milled too thin. The first attribute can include at least one of a position, shape, or size of each tracking feature of the first set of tracking features. Adjusting the first milling setting is based on the comparison. The method may further comprise adjusting the first milling setting when the comparison is greater than a predetermined value. The predetermined value includes one of a predetermined distance or a predetermined angle. Determining the second set of tracking features includes determining a second attribute of the second set of tracking features; determining the second change includes determining a second attribute change to the second attribute; and performing the comparison includes comparing the first attribute change and the second attribute change. The first attribute change includes a first position change and the second attribute change includes a second position change; and adjusting the first milling setting includes adjusting the first milling setting based on the first position change and the second position change. Adjusting the first milling setting includes adjusting the first milling setting based on the first direction and the second direction. Adjusting the first milling setting includes adjusting the first milling setting based on the angle. Adjusting the first milling setting includes adjusting the first milling setting based on the first position change and the second position change. Determining the first set of tracking features includes identifying features of a sample with an artificial intelligence model used for image processing. The artificial intelligence model includes a zero-shot foundational model. Adjusting the first milling setting includes adjusting at least one of a current used to generate an ion beam used to mill the sample, a position of the sample, or a position of the ion beam. Performing the milling operation at the first time and the second time includes milling a first portion of the sample, and the method may further comprise performing, with the charged particle system having the second milling setting, a third milling operation on the sample at a third time at a second portion of the sample different than the first portion.

Another aspect of the disclosure provides for a system including one or more computing devices. The system also includes memory storing instructions, the instructions being executable by the one or more computing devices, where the one or more computing devices are configured to perform, with a charged particle system having a first milling setting, a first milling operation on a sample at a first time. The one or more computing devices are also configured to generate a first image of the sample based on the first milling operation. The one or more computing devices are also configured to determine, based on the first image, a first set of tracking features of the sample. The one or more computing devices are also configured to perform, with the charged particle system having the first milling setting, a second milling operation on the sample at a second time. The one or more computing devices are also configured to generate a second image of the sample based on the second milling operation. The one or more computing devices are also configured to determine, based on the second image, a first change to the first set of tracking features. The one or more computing devices are also configured to adjust the first milling setting to a second milling setting based on the first change.

Implementations may include one or more of the following features. Determining the first set of tracking features includes determining a first attribute of the first set of tracking features; determining the first change includes determining a first attribute change to the first attribute; and adjusting the first milling setting includes adjusting the first milling setting based on the first attribute change. Determining the first set of tracking features includes identifying features of a sample with artificial intelligence model used for image processing.

Yet another aspect of the disclosure provides for a non-transitory computing-device readable storage medium on which computing-device readable instructions of a program are stored. The instructions, when executed by one or more computing devices, causing the one or more computing devices to perform a method, comprising performing, with a charged particle system having a first milling setting, a first milling operation on a sample at a first time. The method also includes generating a first image of the sample based on the first milling operation. The method also includes determining, based on the first image, a first set of tracking features of the sample. The method also includes performing, with the charged particle system having the first milling setting, a second milling operation on the sample at a second time. The method also includes generating a second image of the sample based on the second milling operation. The method also includes determining, based on the second image, a first change to the first set of tracking features. The method also includes adjusting the first milling setting to a second milling setting based on the first change.

### BRIEF DESCRIPTION OF THE DRAWINGS

A further understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 depicts a simplified cross-sectional view of an example charged particle system according to embodiments of the disclosure.

FIG. 2 depicts a sample according to embodiments of the disclosure.

FIG. 3 depicts an unsegmented image of a front view of a sample according to embodiments of the disclosure.

FIG. 4A depicts a first processed image of a front view of a sample at a first time according to embodiments of the disclosure.

FIG. 4B depicts a second processed image of a front view of a sample at a second time according to embodiments of the disclosure.

FIG. 4C depicts a third processed image of a front view of a sample at a third time according to embodiments of the disclosure.

FIG. 4D depicts a third processed image of a front view of a sample at a fourth time according to embodiments of the disclosure.

FIG. 5A depicts a first set of processed images of a lamella at a first time at various profile views according to embodiments of the disclosure.

FIG. 5B depicts a second set of processed images of a lamella at a second time at various profile views according to embodiments of the disclosure.

FIG. 6A depicts a first set of processed images of a lamella at a first time at various profile views according to embodiments of the disclosure.

FIG. 6B depicts a second set of processed images of a lamella at a second time at various profile views according to embodiments of the disclosure.

FIG. 7A depicts a first set of processed images of a lamella at a first time at various profile views according to embodiments of the disclosure.

FIG. 7B depicts a second set of processed images of a lamella at a second time at various profile views according to embodiments of the disclosure.

FIG. 8A depicts a first set of processed images of a lamella at a first time at various profile views according to embodiments of the disclosure.

FIG. 8B depicts a second set of processed images of a lamella at a second time at various profile views according to embodiments of the disclosure.

FIG. 9 depicts a flowchart for adjusting a milling process to correct lamella deformation.

FIG. 10 depicts a block diagram of an example computer system usable with systems and methods according to embodiments of the present disclosure.

### DETAILED DESCRIPTION

Charged particle microscopy is used in various industries, including the semiconductor industry, to analyze micrometer and nanometer scale structures. For example, semiconductor devices can include nanometer scale transistors densely arranged within a silicon wafer. Images obtained with charged particle microscopy can be used to improve process control, evaluate the quality of fabricated devices, and improve yields. In the case of semiconductor devices, objects like field effect transistors (FETs) may be formed within the larger silicon wafer and adjacent to several other structures, including other FETs, vias, diode junctions, and the like. Because of the extremely small scale and dense packing of the elements, imaging of these elements can be improved by careful preparation of the sample.

Imaging samples with a charged particle microscope can include using a transmission electron microscope (TEM), a scanning electron microscope (SEM), a scanning TEM (STEM), or related techniques. To image samples using these techniques, a lamella is formed and removed from the larger substrate (e.g., the silicon wafer). The lamella can include the structures forming the devices (e.g., FETs). The lamella can be formed and removed using a dual beam charged particle microscope system, which typically includes a focused ion beam (FIB) and a SEM. During the lamella formation process, the FIB is used to remove material from the substrate, leaving the lamella as a portion of the remaining material, while the SEM is used for imaging to guide the FIB process. This process has become conventional in many industries, not just the semiconductor industry, and is used to image and analyze almost any type of micron or nanometer scale structure buried within a surrounding substrate.

Once a lamella has been removed from the surrounding material, additional milling with the FIB can be performed to further mill the lamella. For example, an initial lamella sample from a substrate can be formed with a thickness on the order of 1 μm. Milling the lamella in one or more steps with various ion beam energies (e.g., 30 kV, 2 kV, or the like) can reduce a portion of the initial lamella sample to thicknesses of less than 200 nm, including, for example, thicknesses of 150 nm, 100nm, 50 nm, 20 nm, 15 nm, or less than 10 nm. By milling the lamella, image resolution of structures within the lamella can be improved.

In the case of semiconductor devices, the continued development of smaller scale structures that are more closely packed within their substrate has led to challenges in forming suitable lamellas for imaging purposes. Small scale structures may be arranged in several layers within the same substrate, such that structures of layers in front of or behind the structure of interest can obscure or occlude the structure of interest during imaging. For example, a lamella can include a line of transistor elements (e.g., semiconductor channel fins) spaced apart from another line of transistor elements by 50 nm. To image only one line of transistor elements, the lamella can be milled to remove the material containing the other line of transistor elements. In some examples, the device lines can be spaced apart by 20 nm or less, so that it may be desirable to prepare lamellae having thicknesses less than 20 nm.

One issue may include lamella deformation (e.g., a portion of the lamella curling, bending, twisting, warping, or otherwise undergoing undesired structural changes) when performing the final milling of the lamella (e.g., milling the lamella below a thickness of 100 nm). At this thinness, the lamella may lack the structural support to withstand internal stresses, which can cause the lamella to be at a greater risk of deformation. Additionally, the lamella may deform at these thicknesses when receiving a charge (e.g., 30 kV). Lamella deformation can cause distorted images when imaged later and, in some embodiments, may be too deformed for use. As such, it would be beneficial to detect when the lamella is deformation.

Conventional methods of detecting lamella deformation may take too much time to be feasible. For example, digital image correlation may be used to detect lamella deformation by detecting changes along all portions of the image to detect structural changes along the lamella. However, because the entire image is being processed in order to detect changes, this method may take a long time (e.g., 5-10 minutes). By the time lamella deformation is detected, the lamella may be too deformed to be usable. As such, the long processing times of conventional lamella deformation are unable to reliably detect lamella deformation for practical real-time use.

The present disclosure addresses this issue by detecting the change in location of certain features of the lamella between multiple images of the lamella using an artificial intelligence model trained for image processing (e.g., an image segmentation model). For example, the method may include using the artificial intelligence model to track sets of tracking features between images of a lamella taken at different times as the lamella is being milled. Changes to these sets of tracking features may indicate geometric changes to the lamella. As such, when changes to the sets of tracking features indicate that the lamella may be beginning to deform, adjustments may be made to the milling process to mitigate, correct, or stop further deformation to the lamella. Because the method of the present disclosure uses the artificial intelligence model, the time required to analyze the change in the sets of tracking features may be drastically decreased. In particular, the artificial intelligence model may look at the changes of the tracking features only at certain discrete portions of the images, thus decreasing the amount of the image that needs to be analyzed in order to determine the changes to the tracking features.

This increased image processing efficiency may allow for the detection of lamella deformation to occur in real-time, thus allowing for adjustments to be made to the milling process before the lamella is deformed further.

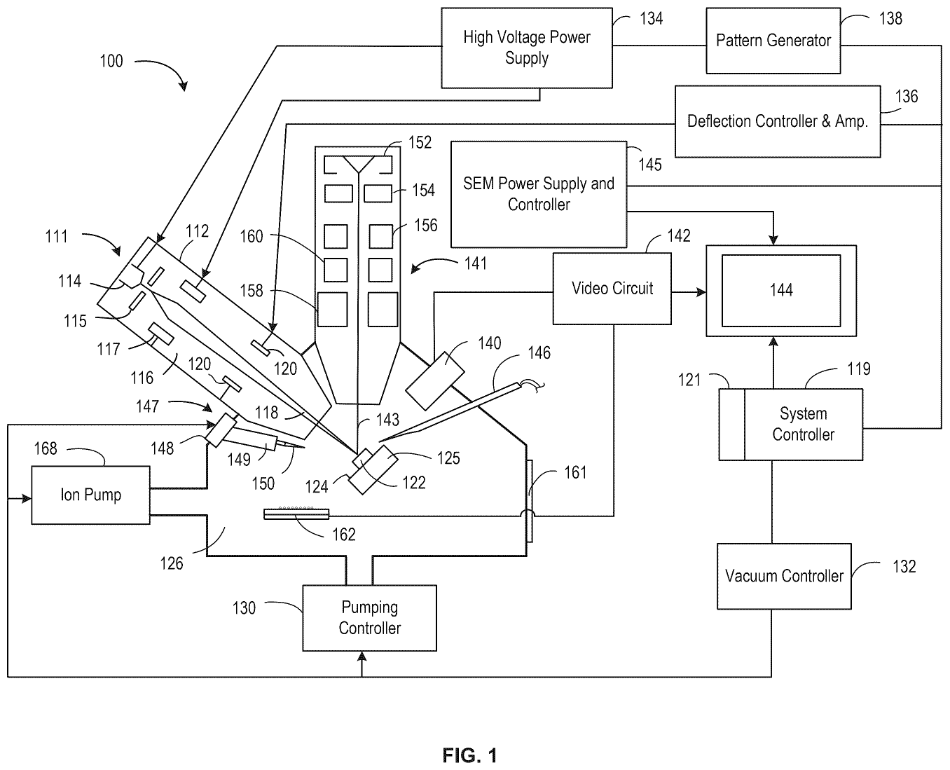

FIG. 1 depicts a schematic diagram of an example charged particle system 100. While an example of suitable hardware is provided below, the invention is not limited to being implemented in any particular type of hardware. The charged particle system 100 may be a dual beam system including an SEM 141 and a FIB system 111. In some embodiments, the FIB system 111 can include a plasma FIB system.

The SEM 141, along with power supply and control unit 145, is provided with the charged particle system 100. An electron beam 143 is emitted from a cathode 152 within an electron column 155 by applying voltage between cathode 152 and an anode 154. Electron beam 143 is focused to a fine spot by means of a condensing lens 156 and an objective lens 158. Electron beam 143 is scanned two-dimensionally on the specimen by means of a deflector 160. Operation of condensing lens 156, objective lens 158, and deflector 160 is controlled by power supply and control unit 145.

Electron beam 143 can be focused onto sample 122, which is on stage 125 within sample chamber 126. Sample 122 may be located on a surface of stage 125 or on TEM sample holder 124, which extends from the surface of stage 125. When the electrons in the electron beam strike sample 122, secondary electrons are emitted. These secondary electrons are detected by secondary electron detector 140. In some embodiments, STEM detector 162, located beneath the TEM sample holder 124 and the stage 125 collects electrons that are transmitted through the sample mounted on the TEM sample holder.

The FIB system 111 comprises an evacuated chamber having an ion column 112 within which are located an ion source 114 and focusing components 116 including extractor electrodes and an electrostatic optical system. The axis of focusing column 116 may be tilted from the axis of the electron column 155 (e.g., at 52 degrees or the like). The ion column 112 includes an ion source 114, an extraction electrode 115, a focusing element 117, deflection elements 120, which operate in concert to form focused ion beam 118. Focused ion beam 118 passes from ion source 114 through focusing components 116 and between electrostatic deflection means schematically indicated at 120 toward sample 122, which may comprise, for example, a semiconductor wafer positioned on movable stage 125 within sample chamber 126. In some embodiments, a sample may be located on TEM grid holder 124, where the sample may be a chunk extracted from sample 122. The chunk may then undergo further processing with the FIB to form a final lamella of a desired thickness in accordance with techniques disclosed herein.

Stage 125 can move in a horizontal plane (X and Y axes) and vertically (Z axis). Stage 125 can also tilt and rotate about the Z axis. In some embodiments, a separate TEM sample stage 124 can be used. Such a TEM sample stage will also preferably be moveable in the X, Y, and Z axes as well as tiltable and rotatable. In some embodiments, the tilting of the stage 125/TEM holder 124 may be in and out of the plane of the ion beam 118, and the rotating of the stage is around the ion beam 118. As used herein to illustrate the disclosed techniques, such relationship will be maintained when discussing rotation and tilting of a sample. Of course, the opposite definitions could be used but would still fall within the contours of the present disclosure.

A door 161 is opened for inserting sample 122 onto stage 125. Depending on the tilt of the stage 124/125, the Z axis will be in the direction of the optical axis of the relevant column. For example, during a data gathering stage of the disclosed techniques, the Z axis will be in the direction, e.g., parallel with, the FIB optical axis as indicated by the ion beam 118. In such a coordinate system, the X and Y axis will be referenced from the Z-axis. For example, the X-axis may be in and out of the page showing FIG. 1, whereas the Y-axis will be in the page, all while all three axes maintain their perpendicular nature to one another.

An ion pump 168 is employed for evacuating the neck portion. The chamber 126 is evacuated with turbomolecular and mechanical pumping system 130 under the control of vacuum controller 132. The vacuum system provides within chamber 126 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁵ Torr.

The high voltage power supply provides an appropriate acceleration voltage to electrodes in focusing column 116 for energizing and focusing ion beam 118. When it strikes sample 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing components 116 for forming an approximately 1 keV to 60 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of sample 122. In some systems the deflection plates are placed before the final lens, as is well known in the art. Beam blanking electrodes (not shown) within ion beam focusing column 116 cause ion beam 118 to impact onto blanking aperture (not shown) instead of sample 122 when a blanking controller (not shown) applies a blanking voltage to the blanking electrode.

The ion source 114 typically provides an ion beam based on the type of ion source. In some embodiments, the ion source 114 is a liquid metal ion source that can provide a gallium ion beam, for example. In other embodiments, the ion source 114 may be plasma-type ion source that can deliver a number of different ion species, such as oxygen, xenon, and nitrogen, to name a few. The ion source 114 typically is capable of being focused into a sub one-tenth micrometer wide beam at sample 122 or TEM grid holder 124 for either modifying the sample 122 by ion milling, ion-induced etching, material deposition, or for the purpose of imaging the sample 122.

A charged particle detector 140, such as an Everhart-Thornley detector or multi-channel plate, used for detecting secondary ion or electron emission is connected to a video circuit 142 that supplies drive signals to video monitor 144 and receiving deflection signals from a system controller 119. The location of charged particle detector 140 within sample chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may comprise precision electric motors 148 positioned outside the vacuum chamber to provide X, Y, Z, and theta control of a portion 149 positioned within the vacuum chamber. The micromanipulator 147 can be fitted with different end effectors for manipulating small objects. In the embodiments described herein, the end effector is a thin probe 150.

A gas delivery system 146 extends into sample chamber 126 for introducing and directing a gaseous vapor toward sample 122. For example, iodine can be delivered to enhance etching, or a metal organic compound can be delivered to deposit a metal.

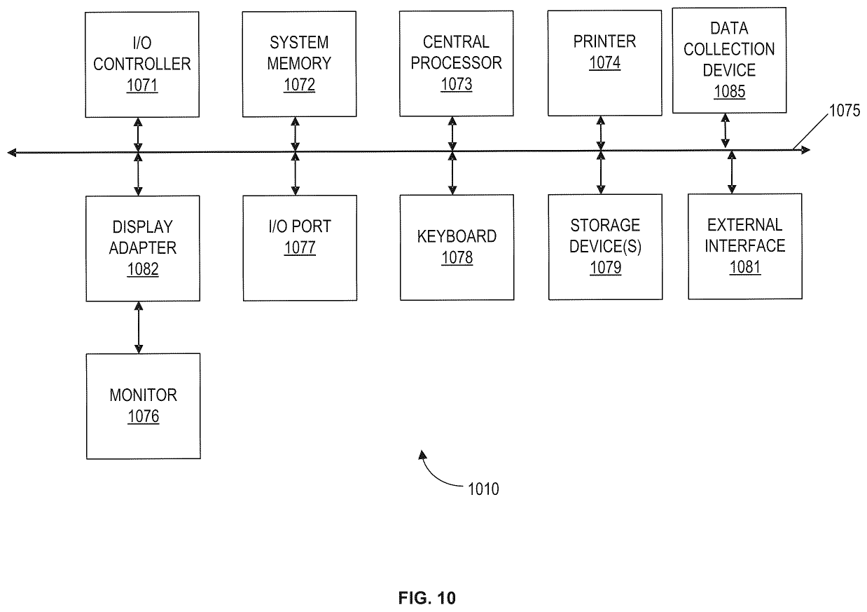

System controller 119 controls the operations of the various parts of charged particle system 100. In some embodiments, the system controller 119 may be a computer system (e.g., the computer system 1010, as shown in FIG. 10). Through system controller 119, a user can cause ion beam 118 or electron beam 143 to be scanned in a desired manner through commands entered into a conventional user interface (not shown). Alternatively, system controller 119 may control charged particle system 100 in accordance with programmed instructions stored in a memory 121.

In operation in accordance with the techniques disclosed herein, system 100 images a working surface (e.g., a cutface) of a sample 122, the sample 122 being a chunk previously removed from a substrate. The chunk, which may be about 1 μm in thickness, may be attached to TEM holder 124 in this example. As used herein, the working surface is a side surface of the chunk, the chunk needing to be milled into a final lamella thickness. The sample 122 may include structures that should be aligned/oriented to the ion beam 118, such as in terms of rotation and/or tilt, so that during the final lamella formation, structures that require subsequent imaging are not removed. The image of the newly exposed surface can be acquired using either the electron column 155 or the FIB 111.

Layers of sample 122 can be removed from the working surface. The removal of a layer may be performed using FIB milling or ion induced etching using a gas precursor. Layers can be removed in smaller “slices” according to certain embodiments, in which slices of about 1 nm to 5 nm are removed sequentially. After the slice is removed, the newly exposed surface is imaged. The process of image acquisition and slice removal may be repeated for 25, 50, 75, or 100 times, but any other number of slices are contemplated herein. The working surface of the lamella can show structures, such as lines of devices including FETs, which are desired to be imaged and/or analyzed.

The removal of a layer of material from the sample 122 can be done by directing the FIB 111 toward a portion of the sample 122 in a pattern. For example, the ion beam 118 may raster over the surface of the sample 122 in the portion, removing the desired layer. As described in more detail below, the system controller 119 can be configured to direct the ion beam 118 over a portion of the sample to vary the dose of the FIB 111 applied to any point in the portion of the sample. For example, the FIB 111 can raster more quickly at one portion of the surface of the sample 122, thereby having a lower dose since the FIB 111 may not deposit as much energy to the sample at each point in the raster. At another portion of the surface of the sample 122, the FIB 111 can raster more slowly, thereby having a higher dose in this portion. The variation in dose for the pattern may be linear or non-linear, depending on the desired characteristics of the FIB 111 during the milling process.

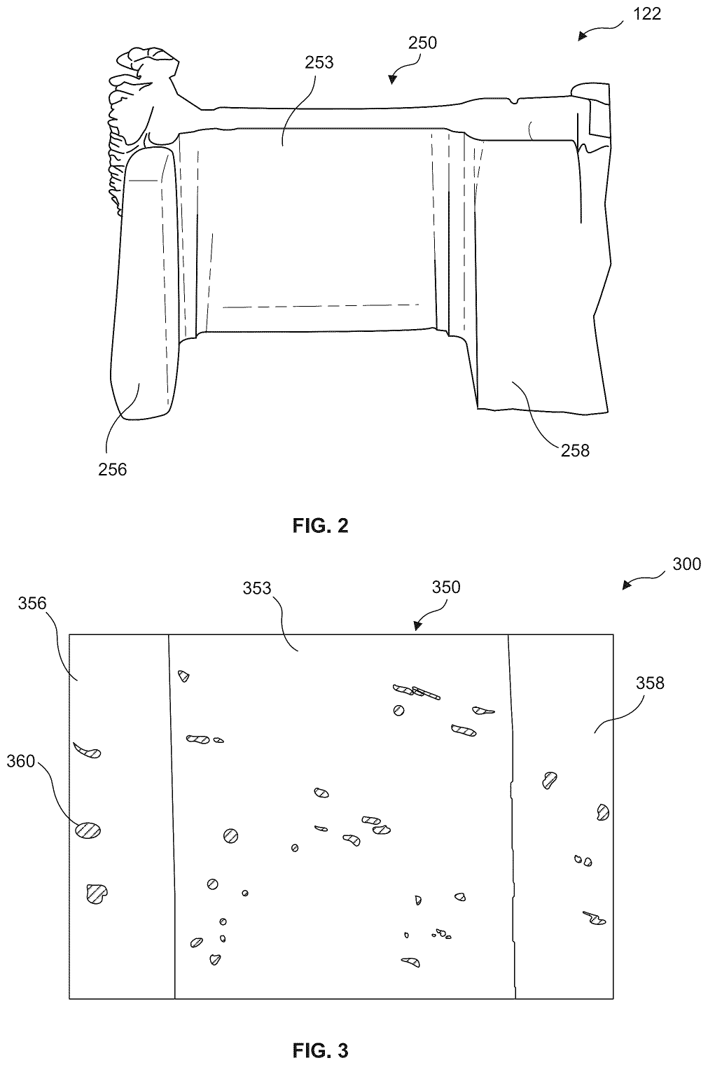

FIG. 2 depicts a lamella 250 formed from the sample 122. It is understood that features ending in like reference numerals as features discussed above are similar, except as noted below. The lamella 250 may be formed from the sample 122 via an initial formation technique, for example a cut and lift out technique. The sample 122 may include a first body portion 256 and a second body portion 258. The body portions 256, 258 may correspond to a portion of the sample 122 that been milled less than the lamella 250 (e.g., portions of the sample 122 that have not been milled by the FIB 111). The lamella 250 may include a cutface 253 that is imaged to detect deformation.

As discussed above, as the lamella 250 is milled by the FIB 111, the lamella 250 may become more delicate and may be placed at a greater risk of undergoing deformation from the internal stresses of the lamella 250. Additionally, the lamella 250 may be deformed from the charges applied to the sample 122 by the ion beam 118. Conventional techniques may include using digital image correlation to detect deformation of the lamella 250. However, these conventional techniques are inefficient and may result in a slower deformation detection process. The present disclosure addresses this issue by determining and tracking changes features of the lamella 250 using an artificial intelligence model trained for image processing, resulting in faster deformation detection speeds.

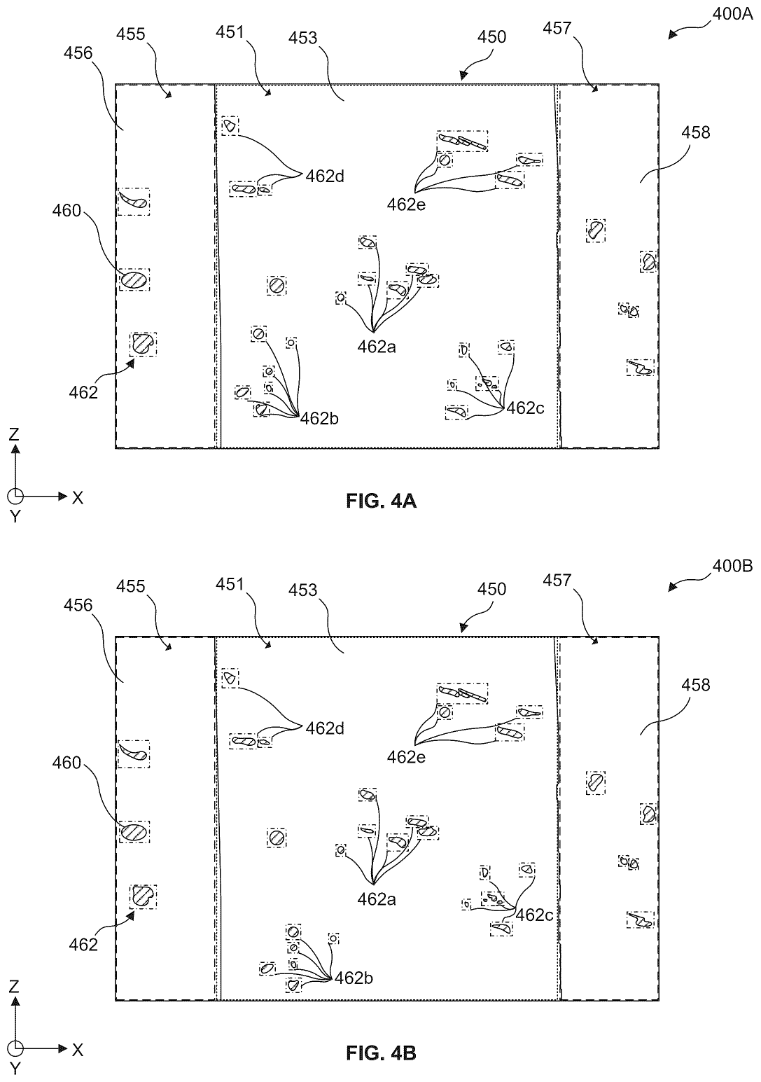

FIG. 3 depicts an unsegmented image 300 of a front view of a sample. It is understood that features ending in like reference numerals as features discussed above are similar, except as noted below. The unsegmented image 300 may be an image depicting a sample as the sample is being milled prior to being processed by an artificial intelligence model. The unsegmented image 300 may be an image of the sample prior to any image analysis. The unsegmented image 300 may include a lamella image portion 350 and a cutface image portion 353 corresponding to a lamella and a cutface (e.g., the lamella 250 and cutface 253, as shown in FIG. 2). The unsegmented image 300 may include a first body image portion 356, and a second body image portion 358 corresponding to body portions of a sample (e.g., the body portions 256, 258, as shown in FIG. 2). In some embodiments, the body image portions 356, 358 may correspond to any feature of a sample that is not the lamella.

The unsegmented image 300 may depict a plurality of feature images 360 on the various image portions 350, 352, 354, 356, 358. The feature images 360 may be represented by the portions of the unsegmented image 300 having a cross-hatching. The feature images 360 may be images of irregularities or discrete features appearing on a sample. As will be described below, in some embodiments, one or more of the feature images 360 may correspond with an electrical component, such as a transistor, or a portion of an electrical component. In other embodiments, the unsegmented image may have any number and shape of feature images corresponding to the number and shape of features along the sample. As will be described below, the position of these feature images 360 may be identified and tracked to determine whether any portion of the sample in the unsegmented image 300 (e.g., a lamella of the sample) may begin deformation.

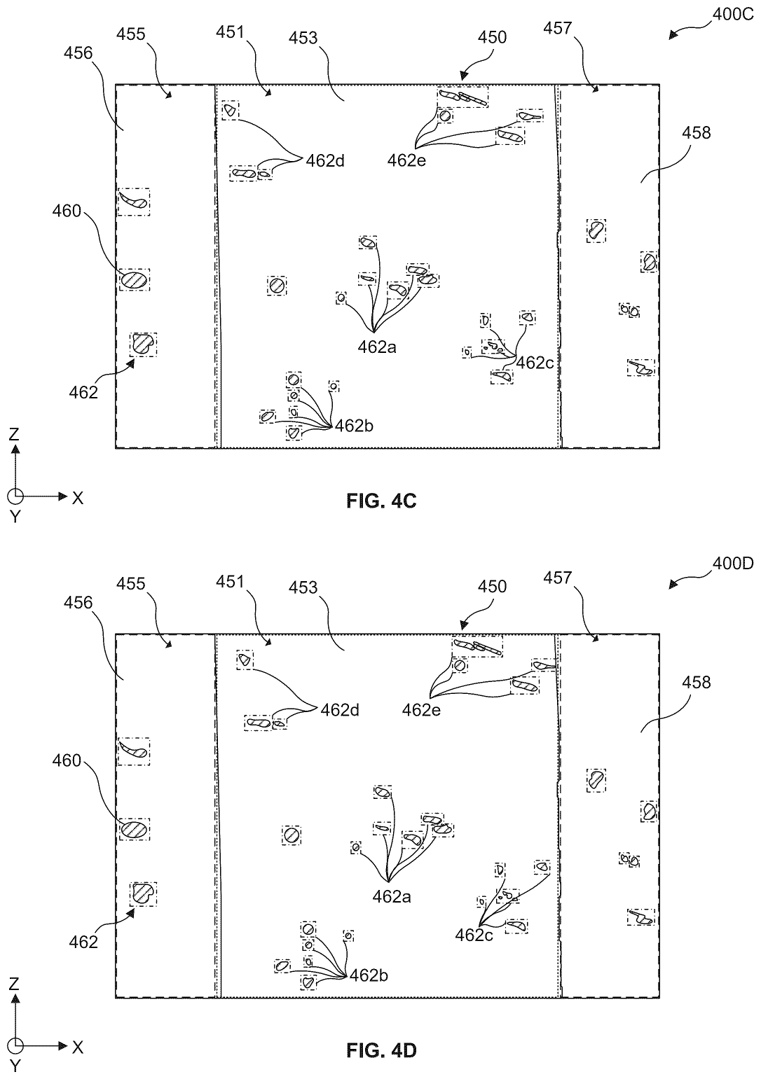

For example, FIGS. 4A-4D depicts processed images of a sample during a milling process that have been processed by an artificial intelligence model (e.g., segmented by an image segmentation model). In particular, FIG. 4A depicts a first processed image 400A of a sample at a first time, FIG. 4B depicts a second processed image 400B of the sample at a second time after the first time, FIG. 4C depicts a third processed image 400C of the sample at a third time after the second time, and FIG. 4D depicts a fourth processed image 400D of the sample at a fourth time after the third time. It is understood that features ending in like reference numerals as features discussed above are similar, except as noted below.

Turning first to FIG. 4A, the first processed image 400A may be unsegmented images of the sample during a milling process (e.g., the first image 300) that has certain features identified by an artificial intelligence model. For example, the artificial intelligence model may identify and segment the lamella image portion 450, the body image portions 456, 458, and the feature images 460. In particular, a computer system may identify the lamella image portion 450 as the lamella bounded arca 451, the first body image portion 456 as the first body bounded area 455, the second body image portion 458 as the second body bounded area 457, and the feature images 460 as the tracking features 462.

The body bounded areas 455, 457 may be depicted as boxes with a dashed line. The lamella bounded area 451 may be depicted as the box with a half-dashed line. The tracking features 462 may be depicted by boxes with a dash-dotted line. It should be understood that the type of box used to identify the lamella image portion 450, the body image portions 456, 458, and the feature images 460 (e.g., dashed line, half-dashed line, and dash-dotted line) are merely illustrative and that any type of box having any geometry can be used. There may be any number of tracking features 462 corresponding to any number of feature images 460 identified by the computer system.

The boxes depicted by the bounded areas 451, 455, 457 and the tracking features 462 may be visual representations overlaid on the segmented images of the sample while milling such that a user viewing the processed images 400A, 400B, 400C, 400D may view the areas of the processed images 400A, 400B, 400C, 400D identified and segmented by the computer system with the artificial intelligence model as corresponding to the lamella image portion 450, the body image portions 456, 458, and the feature images 460. In other embodiments, the visual representations of the bounded areas and the tracking features may not be displayed to perform the method described in the disclosure. In other words, a computer system may identify and segment the image without displaying the boxes of the bounded areas and tracking features.

The artificial intelligence model may be a machine-learning model trained to identify different portions of an image sample while being milled to form a lamella. In particular, the artificial intelligence model may be a software model that is trained to recognize portions of an unsegmented image (e.g., the unsegmented image 300, shown in FIG. 3) that may correspond to the lamella (e.g., the lamella image portion 450) and portions of an unsegmented image that may correspond to the portions of the sample that are not the lamella (e.g., the body image portions 456, 458). For example, the artificial intelligence model may include a segmentation model that identifies and segments portions of images for tracking over multiple images. Additionally, the artificial intelligence model may be trained to recognize discrete aesthetic features of an image of the sample and identify them as tracking features 462.

In another example, the artificial intelligence model may be trained to identify features based on features may include one or more pixels in an image having a relative difference in brightness, saturation, color, or other visual quality compared to the surrounding pixels in an image. The artificial intelligence model may identify these features when there are a certain amount of pixels grouped together (e.g., at least one, two, five, ten, or the like). However, in other embodiments, the artificial intelligence model may identify only one pixel as a feature. In a further embodiment, as will be discussed further below, the artificial intelligence model may identify a set of features close to each other as a set of tracking features, as discussed further below.

As will be described further below, a computer system may determine that the changes in these tracked features may correspond to changes in a sample while being milled. In some embodiments, the computer system may train the artificial intelligence model to determine the type of changes in the sample based on the changes of the tracked features. For example, the artificial intelligence model may be trained to determine what type of deformation the sample is undergoing based on the changes to the tracked features. This may include determining whether the sample is undergoing curling, bending, twisting, warping, or other types of physical changes to the sample. Additionally, the artificial intelligence model may also be trained to determine which portion of the sample (e.g., which edge portion, which corner portion, or the like) is undergoing the change based on the changes to the tracked features.

The artificial intelligence model may be trained by tuning weights based on a stored collection of data to determine a relationship between inputs and outputs. Specifically, the artificial intelligence model may be a computer vision technique trained with a large collection of data (e.g., greater than 100 hundred images of samples being milled, greater than 1,000 images, greater than 10,000 images, or the like) to identify certain portions of an image as corresponding to the lamella image portion 450, the body image portions 456, 458, and the feature images 460. The model may be trained by one or more of unsupervised learning, supervised learning, reinforcement learning, and/or statistical techniques (e.g., regression analysis, least square error analysis, or the like). In one example, the artificial intelligence model may be trained by using a classifier that can train the artificial intelligence model to classify what type of deformation a sample might be undergoing, and/or which portions of the sample is undergoing that change, based on changes in the tracked features between images. The artificial intelligence model may be trained in real-time as the model is being used, however, in other embodiments, the artificial intelligence model may be trained separately prior to use. The artificial intelligence model may include a computer vision model, such as an image segmentation model. One example image segmentation model may include a zero-shot foundational model or any other type of artificial intelligence model trained to track features in between images.

In some embodiments, the computer system may ignore the tracking features 462 within the body bounded areas 455, 457. As the computer system may focus on deformation of the lamella, the computer system may focus on localized movement of the tracking features 462 in the lamella bounded area 451 to determine whether the lamella is deformation. However, in other embodiments, the computer system may track the movement of the tracking features within the body bounded areas.

The tracking features 462 in the lamella bounded area 451 may include as a first set 462a of tracking features 462, a second set 462b of tracking features 462, a third set 462c of tracking features 462, a fourth set 462d of tracking features 462, and a fifth set 462e of tracking features 462. Each set 462a, 462b, 462c, 462d, 462e may represent the position of a set of features detected by the computer system along a cutface of the lamella. As the first set 462a may be positioned in a central portion of the cutface image portion 453, the first set 462a may represent a set of tracking features 462 identified by the computer system as being a central portion of the lamella being milled. The sets 462b, 462c, 462d, 462e may, therefore, correspondingly represent other portions of the lamella, such as the edge portions of the lamella. Although five sets 462a, 462b, 462c, 462d, 462e are depicted, in other embodiments, there may be more or less than five sets depending on the number and grouping of the tracking features in the image.

The computer system may group tracking features 462 into the sets 462a, 462b, 462c, 462d, 462e because movement of a single tracking feature 462, in isolation, may have an increased chance of being an anomaly and not representative of lamella deformation. However, in other embodiments, the computer system may analyze movement of singular tracking features in determining lamella deformation. For example, the computer system may account for the change in position of a singular tracking feature in conjunction with the change in position of nearby sets of tracking features when the single tracking feature is too far from the other sets of tracking features to be considered a part of those sets. Each set 462a, 462b, 462c, 462d, 462e may include at least 2 tracking features 462, at least 5 tracking features 462, or even more tracking features 462. The computer system may group tracking features 462 together when the tracking features 462 are within a certain distance of each other. For example, the tracking features 462 may be grouped together in a set 462a, 462b, 462c, 462d, 462e for the tracking features 462 near each other within about 5% and 30% of an area of the processed image 400A, 400B, 400C, 400D, for the tracking features 462 near each other within about 10% and 20% of the area of the processed image 400A, 400B, 400C, 400D, or any other percentage or defined threshold.

The computer system may track the change in position of the sets 462a, 462b, 462c, 462d, 462e relative to each other between images to determine whether the lamella is deforming. For example, turning to FIG. 4B, the second processed image 400B may be a segmented image of the sample at a second time after additional milling is performed on the sample represented in the first processed image 400A. The second processed image 400B may depict the second set 462b having moved from a first position shown in the first processed image 400A shown in FIG. 4A to a second position in a first direction down along the Z-axis and right along the X-axis shown in FIG. 4B. The second processed image 400B may also depict the third set 462c having moved from a first position of the first set 462a shown in the first processed image 400A of FIG. 4A to a second position in a second direction up along the Z-axis and right along the X-axis. Movement of the sets 462b, 462c from the first processed image 400A to the second processed image 400B may indicate that the features of the lamella represented by the sets 462b, 462c may move from the first processed image 400A to the second processed image 400B. Specifically, movement of the second set 462b in the first direction and the third set 462c in the second direction may indicate, when viewed from a front view similar to FIGS. 4A and 4B, that the portion of the lamella corresponding to the second set 462b has deformed in the first direction while the portion of the lamella corresponding to the third set 462c has deformed in the second direction.

It should be understood that the depicted movement of the second set 462b and the third set 462c from the first processed image 400A to the second processed image 400B, depicted in FIG. 4A and 4B, is merely illustrative. In other embodiments, any of the sets of tracking features may move in any direction/remain stationary between images. For example, the fourth and/or fifth set of tracking features may move in a different direction than the other sets of tracking features. Alternatively, only one set of tracking features may move between images. Additionally, any of the sets of tracking features may move any distance or directions between images.

The computer system may determine that the lamella is deformation from the first processed image 400A to the second processed image 400B because the second set 462b and third sets 462c moves a greater distance relative to one or more of the other sets 462a, 462b, 462c, 462d, 462e. For example, from the first processed image 400A to the second processed image 400B, the second set 462b and the third set 462c may move positions whereas the first set 462a may remain in substantially the same location. This may indicate that the edge portions of the lamella represented by the second set 462b and the third set 462c may move while the central portion of the lamella represented by the first set 462a may have remained substantially stationary. This relative movement of portions of the lamella based on one or more sets 462a, 462b, 462c, 462d, 462e moving while one or more of the other sets 462a, 462b, 462c, 462d, 462e remaining stationary may indicate that the lamella is deforming. Additionally, the computer system may also determine which portions of the lamella are deforming based on which of the sets 462a, 462b, 462c, 462d, 462e are moving relative to one or more of the other sets 462a, 462b, 462c, 462d, 462e.

In some embodiments, in addition or in alternative to the method described above, the computer system may determine that the lamella is deformation from the first processed image 400A to the second processed image 400B based on multiple sets 462a, 462b, 462c, 462d, 462e moving in different directions. For example, the second set 462b and the third set 462c moving from a first position to a second position in different directions from each other may indicate that the edge portion of the lamella corresponding to the second set 462b and the edge portion of the lamella corresponding to the third set 462c are moving in different directions from each other. This relative movement of portions of the lamella based on one or more sets 462a, 462b, 462c, 462d, 462e moving in one direction while one or more of the other sets 462a, 462b, 462c, 462d, 462e moves in another direction may indicate that the lamella is deforming from the first processed image 400A to the second processed image 400B.

The computer system may determine that the lamella is deforming when one or more sets 462a, 462b, 462c, 462d, 462e of tracking features may move, between images, in a similar direction but different distances. For example, turning to FIG. 4C, the third processed image 400C depicts the fourth set 462d and the fifth set 462e both moving upwards from a first position not a second position along the Z-axis in a substantially similar direction from the second processed image 400B. Movement along a substantially similar direction may mean that movement between the fourth set 462d and the fifth set 462e may have less than a 10° deviation from each other, less than a 5° deviation from each other, or have no angular deviation from each other. However, the fourth set 462d and the fifth set 462e may each move a different distance from the second processed image 400B to the third processed image 400C. In particular, the fifth set 462e may move a greater distance than the fourth set 462d from the second processed image 400B to the third processed image 400C. Whereas, as discussed below, movement of the sets 462a, 462b, 462c, 462d in a similar direction and distance may indicate that there is no lamella deformation, this relative difference in distance moved between sets 462d, 462e may indicate that the lamella is deforming.

Additionally, this relative difference in distance may indicate that, although the portions of the lamella corresponding to the sets 462d, 462e are moving in a similar direction, the portion of the lamella corresponding to the fifth set 462e is moving at a greater relative speed than the portion of the lamella corresponding to the fourth set 462d. These differences in relative speed may indicate that one of the portions of the lamella corresponding to the sets 462d, 462e may be deforming at a greater speed than others (e.g., the fifth set 462e deforming at a greater speed than the fourth set 462d).

The computer system may determine that movement of all sets 462a, 462b, 462c, 462d, 462e along a substantially similar direction and distance may not indicate deformation. For example, turning to FIG. 4D, the fourth processed image 400D depicts the sets 462a, 462b, 462c, 462d, 462e each moving right along the X-axis a substantially similar distance from a first position in the third processed image 400C to a second position in the fourth processed image 400D. Moving a substantially similar distance may mean that each of the sets 462a, 462b, 462c, 462d, 462e may move a distance within about a 10% deviation of each other, such as about a 5% deviation, or being completely the same. Movement of all sets 462a, 462b, 462c, 462d, 462e along a substantially similar direction and distance may indicate that all portions of the lamella corresponding to the sets 462a, 462b, 462c, 462d, 462e may be an indication that, although the lamella as a whole is moving (e.g., from a shift in the camera taking the image of the lamella, a shift in direction of the sample, or the like), the lamella is not undergoing deformation from the third processed image 400C to the fourth processed image 400D.

In some examples, movement of the first set 462a without movement of the other sets 462b, 462c, 462d, 462e may be a false positive. In this example, the computer system may disregard the movement of the first set 462a in determining whether the lamella is deforming. However, in other embodiments, movement of the first set 462a by itself can indicate that the lamella is deforming. For example, this kind of movement may indicate that a central portion of the lamella is bulging.

In some embodiments, the computer system may determine whether the sets 462b, 462c, 462d, 462e undergo a sufficient change in attributes over the processed images 400A, 400B, 400C in order for the computer system to determine that the lamella is deforming. For example, turning specifically to the portion of the lamella corresponding to the second set 462b shown in FIGS. 4A and 4B, the computer system may determine whether a first distance between a first position of the second set 462b in the first processed image 400A and a second position of the second set 462b in the second processed image 400B is sufficiently greater than a second distance between a first position of one of the other sets 462a, 462c, 462d, 462e in the first processed image 400A and a second position of one of the other sets 462a, 462c, 462d, 462e in the second processed image 400B (e.g., a second distance between a first position of the first set 462a in the first processed image 400A and a second position of the first set 462a in the second processed image 400B). In some embodiments, the computer system may determine that there is deformation at the portion of the lamella corresponding to the second set 462b when the first distance is greater than the second distance by any amount. However, in other embodiments, the computer system may determine that there is deformation at this portion when the first distance is greater than the second distance by a predetermined distance threshold (e.g., when the difference between the first distance and the second distance is greater than about 5% of a length/width processed images 400A, 400B, 400C, 400D, greater than about 10%, greater than about 20%, or any other percentage or defined threshold). A similar analysis may be performed for the sets 462c, 462d, 462e or, in other embodiments, any sets that change position between processed images.

In some embodiments, the computer system may additionally or alternatively determine whether the direction of the sets 462b, 462c, 462d, 462e, are sufficiently different over the processed images 400A, 400B, 400C, 400D in order for the computer system to determine that the lamella is deforming. For example, turning to the sets 462b, 462c shown in FIGS. 4A and 4B, the computer system whether an angle between a first direction of the second set 462b and a second direction of the third set 462c from the first processed image 400A to the second processed image 400B is greater than a predetermined angle threshold. In some embodiments, the computer system may determine that there is deformation at the portions of the lamella corresponding to the sets 462b 462c when the angle is greater than 0. However, in other embodiments, the computer system may determine that there is deformation at this portion when the angle is greater than about 5°, greater than about 10°, greater than about 15°, or the like. A similar analysis may be performed for any sets that change position between processed images.

In some embodiments, the computer system may determine whether a lamella is deforming based on a combination of the above calculations regarding a difference in relative distance and angles between the changed position of the sets 462a, 462b, 462c, 462d, 462e. For example, the computer system may determine that the lamella is deforming only when both the predetermined distance threshold and the predetermined angle is met. In other examples, the computer system may determine that the lamella is deforming when only one of the predetermined distance threshold and the predetermined angle is met. In one example, where the changed position of the sets 462a, 462b, 462c, 462d, 462e does not meet the predetermined distance threshold by a small margin (e.g., the distance difference is less than about 5% of the length/width of the processed images 400A, 400B, 400C, 400D, less than about 3%, less than about 2%, less than about 1%, or any other percentage or defined threshold) but exceeds the predetermined angle threshold by a large margin (e.g., the angle is greater than about 20°, greater than about 25°, greater than about 30°, or the like), the computer system may determine that the portions of the lamella corresponding to the changed position of the sets 462a, 462b, 462c, 462d, 462e may be deforming. Alternatively, where the changed position of the sets 462a, 462b, 462c, 462d, 462e does not meet the predetermined angle threshold by a small margin (e.g., the angle difference is less than about 5°, less than about 4°, less than about 3°, less than about 2°, less than about 1°, or the like) but exceeds the predetermined distance threshold by a large margin (e.g., the distance difference is greater than about 25% of the length/width of processed images 400A, 400B, 400C, 400D, greater than about 30%, greater than about 35%, or any other percentage or defined threshold), the computer system may determine that the portions of the lamella corresponding to the changed position of the sets 462a, 462b, 462c, 462d, 462e may be deforming.

In some embodiments, the computer system may use a weighted system with the difference in distance and the angle of the changed position of the sets 462a, 462b, 462c, 462d, 462e to determine whether the lamella is deforming. For example, a first weight may be applied to the distance difference and a second weight may be applied to the angle difference to determine a normalized value corresponding to a likelihood that the lamella is deforming. The computer system may determine that the lamella is deforming based on whether the normalized value is greater than a predetermined weighted threshold. For example, where the normalized value is a value between 0 and 1, the computer system may determine that the lamella is deforming when the normalized value is greater than a value of 0.5, greater than a value of 0.7, greater than a value of 0.9, or the like.

As noted above, each of the processed images 400A, 400B, 400C, 400D may be taken at different times from each other. There may be any number of images (e.g., still frames in a video) between each of the processed images 400A, 400B, 400C, 400D. For example, there may be 2 images, 5 images, 10 images, or the like. For example, there may be 5 images between processed images 400A, 400B, 400C, 400D, 10 images, or even more images. In other embodiments, each of the processed images 400A, 400B, 400C, 400D may follow each other consecutively. In some embodiments, the processed images 400A, 400B, 400C, 400D may be taken in between milling. In other words, the processed images 400A, 400B, 400C, 400D may be taken when the lamella is not being actively milled. In yet other embodiments, the processed images 400A, 400B, 400C, 400D may be about taken every 1 ms, 5 ms, 10 ms, 15 ms, 30 ms, 60 ms, or the like. For example, the computer system may include an image recording speed of 30 frames per second (fps), 60 pms, 90 fps, 120 fps, or the like In this manner, the processed images 400A, 400B, 400C, 400D, and subsequent analysis for lamella deformation detection with an artificial intelligence model, can be performed in real-time.

For the processed images 400A, 400B, 400C indicating lamella deformation, the rate of deformation may be correlated with the number of images between each of the processed images 400A, 400B, 400C and the distance of the change in position between each of the sets 462a, 462b, 462c, 462d, 462e. For example, turning to FIGS. 4A and 4B, the change in position for the sets 462b, 462c where the second processed image 400B immediately follows the first processed image 400A (or even where only 1 additional image separates the processed images 400A, 400B from each other) may indicate irreparable lamella deformation as such a drastic change in position of the sets 462b, 462c in such a short time may indicate that the sets 462b, 462c are moving too fast for the milling process to be adjusted to correct that deformation. Conversely, the more images between the processed images 400A, 400B, 400C, the lesser the rate of deformation of the lamella and the greater the chance that the milling process can be adjusted to correct this deformation. In this manner, the computer system may be able to determine the rate of deformation of portions of the lamella based on the change in distance of the moving sets 462a, 462b, 462c, 462d, 462e between processed images 400A, 400B, 400C and how many images are taken between each of the processed images 400A, 400B, 400C.

Although the above disclosure is directed primarily to a change in position of the sets 462a, 462b, 462c, 462d, 462e, in other embodiments, the computer system may also determine whether the lamella is deforming based on a change in size and/or shape of sets of the tracking features. For example, a substantially uniform increase or decrease in size of one or more of the sets may indicate a deformation of the lamella in that area (e.g., a bulging of the lamella). Similarly, a change in shape of one or more of the sets may indicate that the lamella is being deformed at those locations.

Once the computer system determines that the lamella is deforming, the computer system may send a notification (e.g., a visual warning, audio cue, tactile sensation, or the like) to a display when the computer system detects that the lamella is deforming. The notification may also indicate which portions of the lamella is deforming and at what rate.

In some embodiments, the body bounded areas 455, 457 and the lamella bounded area 451 may change over time as the body image portions 456, 458 and the lamella image portion 450 changes (e.g., from the structure and dimensions of the lamella changing). In some embodiments, the tracking features 462 may disappear over time (e.g., may be milled away). In this example, the tracking features 462 that disappear may be disregarded in the above analysis.

In some embodiments, the computer system may adjust the milling process of the lamella once the computer system determines that the lamella is deforming. The computer system may determine what kind of adjustments may be made based on the extent of deformation by the lamella. For example, the computer system may determine that the lamella is too deformed for further milling when there is a large change in distance between the sets 462a, 462b, 462c, 462d, 462e (e.g., the distance difference is greater than about 25% of the length/width of processed images 400A, 400B, 400C, 400D, greater than about 30%, greater than about 35%, or any other defined percentage or defined threshold). Alternatively or additionally, the computer system may determine that the lamella is too deformed when too much time has elapsed since the change in the sets 462a, 462b, 462c, 462d, 462e (e.g., 5 seconds has elapsed since the detected change, 10 seconds, 1 minute, or any other defined time). In this example, the computer system may elect to halt the milling process.

For example, turning back to FIG. 1, the computer system may adjust one or more of a current of the ion beam 118, position of the ion beam 118, or the position of the sample 122 based on the deformation of the lamella. This may include reducing the current of the ion beam 118 to reduce the amount of milling of the sample 122, including stopping the ion beam 118 if the lamella is beginning to become too deformed. Additionally, this may include adjusting a position of the ion beam 118 relative the position of the sample 122 such that the ion beam 118 mills a different portion of the lamella that is not deformed or has undergone minimal deformation. For example, the position of the ion beam 118 and/or the position of the sample 122 may be adjusted relative to each other (e.g., adjusting a tilt of the sample 122, adjusting an angle of the ion beam 118 relative to the sample 122, adjusting a position of the ion beam 118 on the sample 122, or the like) such that the portions of the lamella that are deformed may be milled so that the lamella is substantially planar.

Although FIGS. 4A-4D describe the method of determining whether and where a lamella is deforming based on a front view of the lamella (e.g., depicting a front view of the cutface of the lamella), it is understood that the above method may be performed while viewing the lamella from any angle (e.g., a top view, side view, bottom view, isometric views, or any other viewing angle).

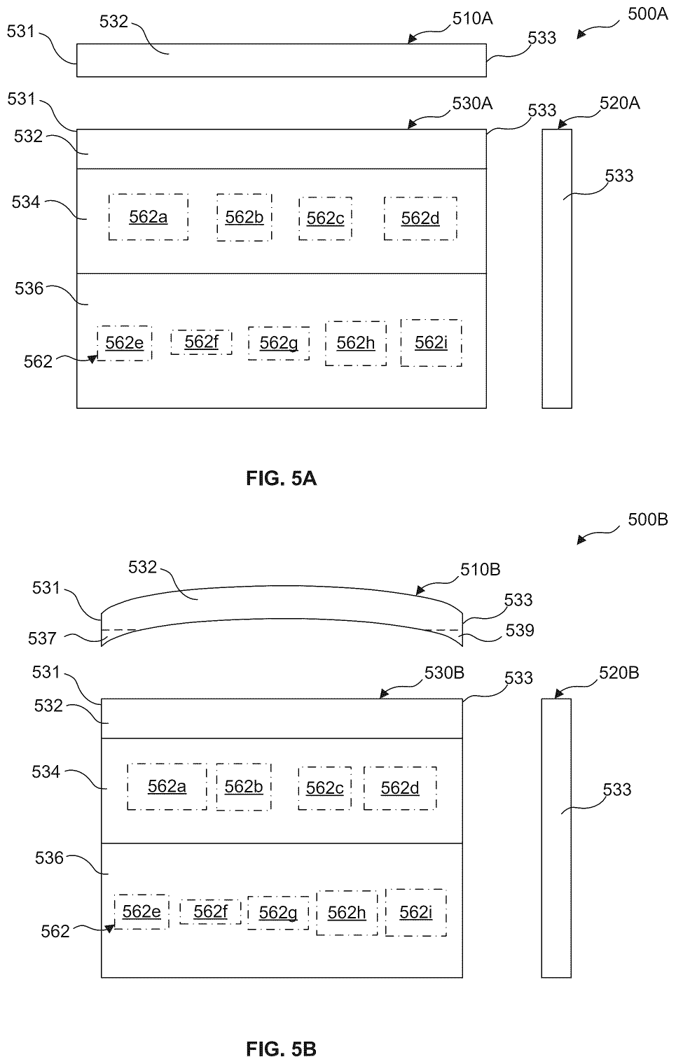

For example, FIGS. 5A and 5B depict sets of schematic images of a lamella at various profile views during a milling process that has been segmented by an artificial intelligence model. It is understood that features ending in like reference numerals as features discussed above are similar, except as noted below. FIG. 5A depicts a first set 500A of a first processed image 510A, a second processed image 520A, and a third processed image 530A of a lamella at a first time. FIG. 5B depicts a second set 500B of a first processed image 510B, a second processed image 520B, and a third processed image 530B of a lamella at a second time. The first processed images 510A, 510B may be an image of a top view of the lamella. The second processed images 520A, 520B may be an image of a side view of the lamella. The third processed images 530A, 530B may be an image of a front view of the lamella, such as a front view of a cutface. For the sake of brevity, the processed images 510A, 510B, 520A, 520B, 530A, 530B may not depict the body image portions (e.g., the body image portions 456, 458, shown in FIGS. 4A-4D) or the bounded areas (e.g., the lamella bounded areas 451, as shown in FIGS. 4A-4D), however, in other embodiments, the processed images may include the body image portions and the bounded areas.

The third processed images 530A, 530B may include a first layer 532, a second layer 534, and a third layer 536. Each of the layers 532, 534, 536 may correspond to a layer of the sample. For example, the first layer 532 may correspond to a protective layer positioned on a top surface of the sample that may protect one or more electronic components of the sample, such as a capping layer. The layers 534, 536 may correspond to layers that each encompass one or more electrical components (or portions of the electrical components) of the sample, such as transistors or the like. In other embodiments any of the layers can have any number of electronic components. Although not shown, these electrical components may be represented as feature images that the computer system may identify to track (e.g., with an artificial intelligence model) as tracking features 562. However, in other embodiments, the tracking features may not correspond to electronic components and, as discussed above, may be other discrete features identified by the computer system along the lamella. Although three layers 532, 534, 536 are depicted, in other embodiments, there may be more or less than three layers, such as one layer, two layers, four layers, or the like. The lamella may have a first lateral side edge depicted by the first side image portion 531 and a second lateral side edge depicted by the second side image portion 533.

As shown in the third processed images 530A, 530B, the second layer 534

may include a first tracking feature 562a, a second tracking feature 562b, a third tracking feature 562c, and a fourth tracking 562d. The third layer 536 may include a fifth tracking feature 562e, a sixth tracking feature 562f, a seventh tracking feature 562g, an eighth tracking feature 562h, and a ninth tracking feature 562i. It should be understood that the number and position of the tracking features 562 are for illustrative purposes and, in other embodiments, there can be any number of tracking features positioned at any position of the third processed image. In yet other embodiments, at least one of the first processed image or the second processed image may include tracking features.

FIG. 5B depicts processed images 510B, 520B of a lamella having undergone deformation from the processed images 510A, 520A along a portion of the lamella adjacent the lateral edges of the lamella (e.g., from the internal stresses of the lamella due to its thin structure). These portions may be deformed such that each of the lateral edges are curved toward each other. In particular, the lamella may be deformed such that the side image portions 531, 533 of the first processed image 510B (corresponding to the lateral edges of the lamella) at the second time are curved down compared to the first processed image 510A at the first time. Due to this deformation, as shown in the third processed image 530B, the width of the lamella may be decreased such that the width defined between the side image portions 531, 533 of the first processed image 510B at the second time is less compared to the first processed image 510A at the first time. Additionally, certain of the tracking features 562 depicted in the third image portion 530B at the second time may have changed positions from the third image portion 530A at the first time corresponding to this deformation. For example, due to the deformation of the lamella, the tracking features 562a, 562d, 562e, 562h, 562i may have laterally changed positions from the first time to a position located toward a center of the third processed image 530B.

As discussed above, the computer system may adjust the milling process of the lamella to address this curvature. For example, the computer system may halt the milling process. Alternatively, the computer system may change a position of the ion beam and/or the sample such that a different portion of the lamella is milled. For example, the computer system may mill the portions of the lamella adjacent the lateral edges, represented by a first corrective mill portion 537 and a second corrective mill portion 539 shown in the first processed image 510B. The lamella may be milled up to the dashed lines depicted in the first processed image 510B, however, it is understood that the location of these dashed lines are merely illustrative and the corrective mill portions may be milled or less than what is shown. Milling these lateral side portions may correct the lamella by reshaping the lamella to be more planar.

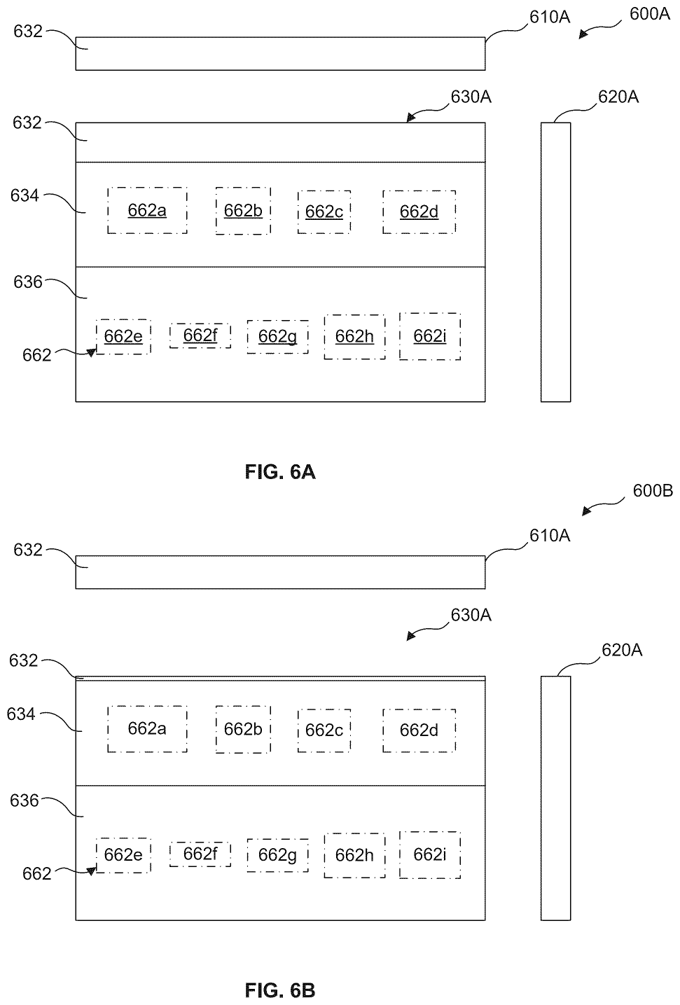

FIGS. 6A and 6B depict schematic images of a lamella during a milling process that has been segmented by an artificial intelligence model. It is understood that features ending in like reference numerals as features discussed above are similar, except as noted below. In particular, FIG. 6B depicts processed images 620B, 630B where the lamella has undergone deformation from the processed images 620A, 630A along a first layer 632 (e.g., the first layer 632 is deformed to be too thin from the current of the ion beam being too strong, focusing too much on the first layer 632 during milling, or the like). The computer system may adjust the milling process to address this deformation by halting the milling process. Alternatively, the computer system may reduce a current of the ion beam and mill a different portion of the lamella.

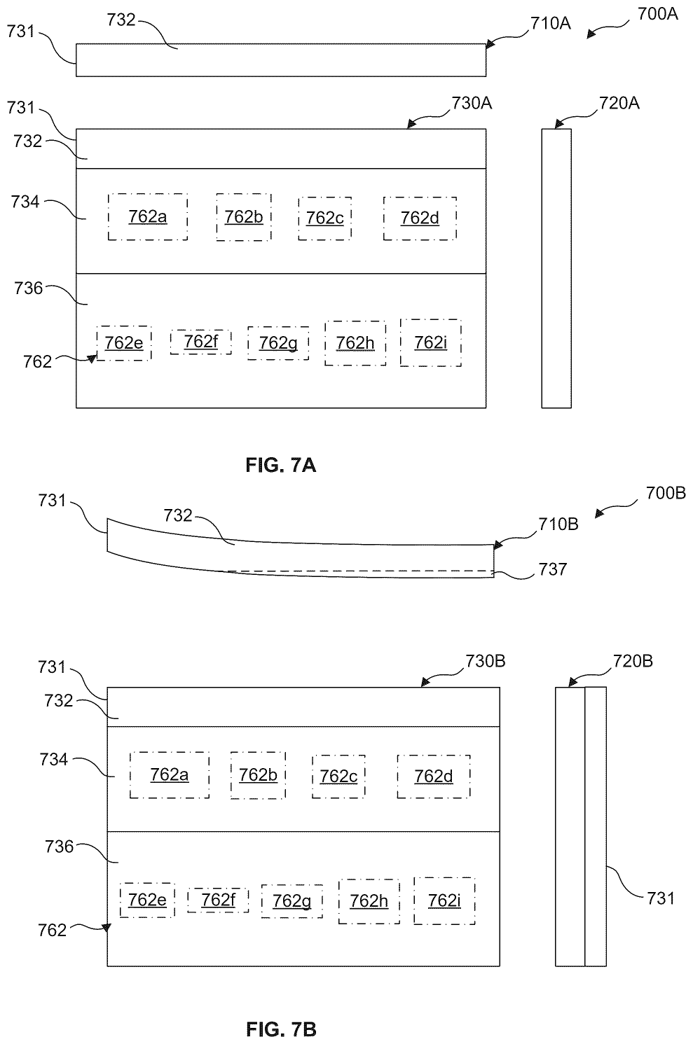

FIGS. 7A and 7B depict schematic images of a lamella during a milling process that has been segmented by an artificial intelligence model. It is understood that features ending in like reference numerals as features discussed above are similar, except as noted below. In particular, FIG. 7B depicts processed images 720B, 730B where the lamella has undergone deformation from the processed images 720A, 730A along a portion of the lamella adjacent a first lateral side edge of the lamella (e.g., from the internal stresses of the lamella due to its thin structure). This portion may be deformed such that the first lateral side edge (e.g., represented by the first side image portion 731) is curved toward a central region of the lamella. Additionally, the tracking features 762a, 762e, 762f may move from a first position at a first time shown in the third processed image 730A laterally inward (e.g., in a rightward direction shown in FIG. 7B) to a second position at a second time shown in the third processed image 730B corresponding to the lamella deformation.

The computer system may adjust the milling process to address this deformation by halting the milling process. Alternatively, the computer system may change a position of the ion beam and/or the sample such that a different portion of the lamella is milled. For example, the computer system may thin the bottom portion of the lamella represented by a corrective mill portion 537 shown in the first processed image 710B. The lamella may be milled up to the dashed lines depicted in the first processed image 710B, however, it is understood that the location of these dashed lines are merely illustrative and the corrective mill portion may be milled or less than what is shown.

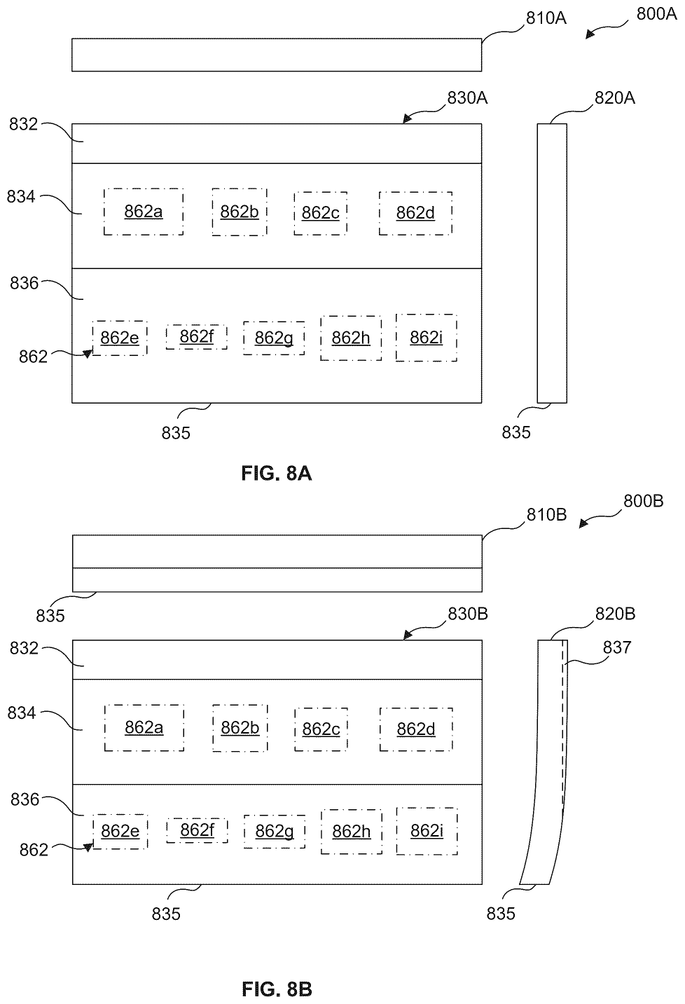

FIGS. 8A and 8B depict schematic images of a lamella during a milling process that has been segmented by an artificial intelligence model. It is understood that features ending in like reference numerals as features discussed above are similar, except as noted below. In particular, FIG. 8B depicts processed images 810B, 820B, 830B where the lamella has undergone deformation from the processed images 810A, 820A, 830A along a portion of the lamella adjacent a bottom edge of the lamella (e.g., from the internal stresses of the lamella due to its thin structure). This portion may be deformed such that the bottom edge (e.g., represented by a bottom edge image portion 835) is curved toward a central region of the lamella. Additionally, the tracking features 862e, 862f, 862g, 862h, 862i may move from a first position at a first time shown in the third processed image 830A in an upward direction shown in FIG. 8B to a second position at a second time shown in the third processed image 830B corresponding to the lamella deformation.

The computer system may adjust the milling process to address this deformation by halting the milling process. Alternatively, the computer system may change a position of the ion beam and/or the sample such that a different portion of the lamella is milled. For example, the computer system may mill the bottom portion of the lamella represented by a corrective mill portion 837 shown in the second processed image 820B. The lamella may be milled up to the dashed lines depicted in the second processed image 820B, however, it is understood that the location of these dashed lines are merely illustrative and the corrective mill portion may be milled or less than what is shown.

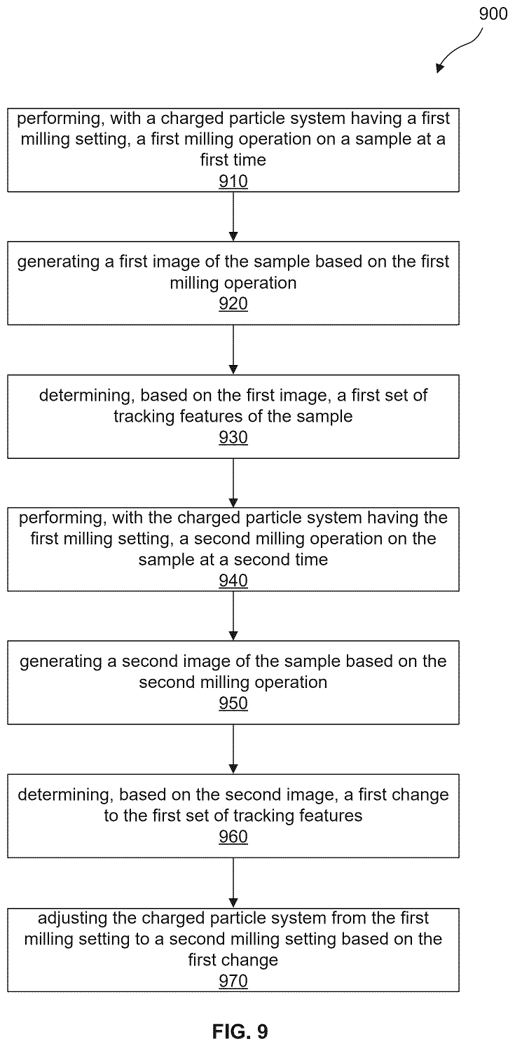

FIG. 9 depicts an example flowchart showing a process 900 for adjusting a milling process to correct lamella deformation. It is understood that features ending in like reference numerals as features discussed above are similar, except as noted below. The below operation of the components of the charged beam particle system can be performed by the computer system 1010 shown in FIG. 10.

Block 910 may include performing, with a charged particle system having a first milling setting, a first milling operation on a sample at a first time. For example, turning to FIG. 1, the charged particle system 100 may mill the sample 122 with an ion beam 118 at a first current setting. Additionally, the sample 122 may have a first sample position (e.g., a first tilt position, rotational position, distance from the ion beam 118, or the like), the ion beam 118 may have a first angle position relative to the sample 122, and the ion beam 118 may be directed to a first position on the sample 122.

Block 920 may include generating a first image 400A of the sample based on the first milling operation. For example, a computer system may generate an unsegmented image 300, shown in FIG. 3, or a first processed image 400A, shown in FIG. 4A.

Block 930 may include determining, based on the first image, a first set of tracking features of the sample. For example, the computer system may determine one or more of the sets 462a, 462b, 462c, 462d, 462e of tracking features 462 of the sample as shown in FIG. 4A

Block 940 may include performing, with the charged particle system having the first milling setting, a second milling operation on the sample at a second time. For example, the charged particle system 100 shown in FIG. 1 may perform a second milling operation on the sample 122 at a second time after the first time.

Block 950 may include generating a second image of the sample based on the second milling operation. For example, turning to FIGS. 4B-4D, a computer system may generate one or more of the processed images 400B, 400C, 400D. The second image 400B, 400C, 400D may be immediately subsequent to the first image (e.g., the first processed image 400A shown in FIG. 4A), however, in other embodiments, the second image may be multiple images after the first image. In some embodiments, the processed images 400A, 400B, 400C, 400D may be taken when the charged particle system is not actively milling the sample (e.g., in between milling operations of the sample).

Block 960 may include determining, based on the second image 400B, 400C, 400D, a first change to the first set of tracking features. For example, the computer system may determine a change to an attribute of the set 462a, 462b, 462c, 462d, 462e of tracking features 462. This may include comparing the latter processed image 400B, 400C, 400D to one of the former processed images 400A, 400B, 400C. The computer system may determine, based on this comparison between the processed images 400A, 400B, 400C, 400D, a change in position of the set 462a, 462b, 462c, 462d, 462e, a direction of that change, a distance of that change, angle of that change, a rate of the change, size, shape, or the like.

The computer system may also determine whether a lamella is deforming based on a relative change of one of the sets 462a, 462b, 462c, 462d, 462e compared to one or more of the other sets 462a, 462b, 462c, 462d, 462e. For example, this may include comparing the changes in attributes of the second set 462b to the changes of in attributes one or more of the other sets 462b, 462c, 462d, 462e from the first processed image 400A to the second processed image 400B. Based on this relative change (e.g., in distance, angle, direction, size, shape, or the like), the computer system may determine that the lamella is deforming. The computer system may determine which portion of the lamella is deforming by determining which sets 462a, 462b, 462c, 462d, 462e have moved more than other and/or moved in a different direction than others.

Block 970 may include adjusting the first milling setting to a second milling setting based on the first change. For example, turning to FIG. 1, the current provided to the ion beam 118, the position of the sample 122, and/or the position of the ion beam 118 may be changed. In some embodiments, the ion beam 118 may be set to a second current setting, such as being deactivated such that the milling process is stopped (e.g., where the lamella is close to being irreparably deformed). In other embodiments, the position of the ion beam 118 and/or the sample 122 may be changed to a second position such that different portions of the lamella are milled (e.g., the corrective mill portions 537, 539 shown in FIG. 5B, the corrective mill portion 737 shown in FIG. 7B, and the corrective mill portion 837 shown in FIG. 8B).

Any of the computer systems mentioned herein (e.g., the computer system housed in the controller system 119) may utilize any suitable number of subsystems. Examples of such subsystems are shown in FIG. 10 in computer system 1010. In some embodiments, a computer system includes a single computer apparatus, where the subsystems can be the components of the computer apparatus. In other embodiments, a computer system can include multiple computer apparatuses, each being a subsystem, with internal components. A computer system can include desktop and laptop computers, tablets, mobile phones and other mobile devices.

The subsystems shown in FIG. 10 are interconnected via a system bus 1075. Additional subsystems such as a printer 1074, keyboard 1078, storage device(s) 1079, monitor 1076 (e.g., a display screen, such as an LED), which is coupled to display adapter 1082, and others are shown. Peripherals and input/output (I/O) devices, which couple to I/O controller 1071, can be connected to the computer system by any number of means known in the art such as input/output (I/O) port 1077 (e.g., USB, Fire Wire®). For example, I/O port 1077 or external interface 1081 (e.g., Ethernet, Wi-Fi, etc.) can be used to connect computer system 1010 to a wide area network such as the Internet, a mouse input device, or a scanner. The interconnection via system bus 1075 allows the central processor 1073 to communicate with each subsystem and to control the execution of a plurality of instructions from system memory 1072 or the storage device(s) 1079 (e.g., a fixed disk, such as a hard drive, or optical disk), as well as the exchange of information between subsystems. The system memory 1072 and/or the storage device(s) 1079 may embody a computer readable medium. Another subsystem is a data collection device 1085, such as a camera, microphone, accelerometer, and the like. Any of the data mentioned herein can be output from one component to another component and can be output to the user.

A computer system can include a plurality of the same components or subsystems, e.g., connected together by external interface 1081, by an internal interface, or via removable storage devices that can be connected and removed from one component to another component. In some embodiments, computer systems, subsystem, or apparatuses can communicate over a network. In such instances, one computer can be considered a client and another computer a server, where each can be part of a same computer system. A client and a server can each include multiple systems, subsystems, or components.

Aspects of embodiments can be implemented in the form of control logic using hardware circuitry (e.g., an application specific integrated circuit or field programmable gate array) and/or using computer software stored in a memory with a generally programmable processor in a modular or integrated manner, and thus a processor can include memory storing software instructions that configure hardware circuitry, as well as an FPGA with configuration instructions or an ASIC. As used herein, a processor can include a single-core processor, multi-core processor on a same integrated chip, or multiple processing units on a single circuit board or networked, as well as dedicated hardware. Based on the disclosure and teachings provided herein, a person of ordinary skill in the art will know and appreciate other ways and/or methods to implement embodiments of the present disclosure using hardware and a combination of hardware and software.

Any of the software components or functions described in this application may be implemented as software code to be executed by a processor using any suitable computer language such as, for example, Java, C, C++, C #, Objective-C, Swift, or scripting language such as Perl or Python using, for example, conventional or object-oriented techniques. The software code may be stored as a series of instructions or commands on a computer readable medium for storage and/or transmission. A suitable non-transitory computer readable medium can include random access memory (RAM), a read only memory (ROM), a magnetic medium such as a hard-drive or a floppy disk, or an optical medium such as a compact disk (CD) or DVD (digital versatile disk) or Blu-ray disk, flash memory, and the like. The computer readable medium may be any combination of such devices. In addition, the order of operations may be re-arranged. A process can be terminated when its operations are completed, but could have additional steps not included in a figure. A process may correspond to a method, a function, a procedure, a subroutine, a subprogram, etc. When a process corresponds to a function, its termination may correspond to a return of the function to the calling function or the main function.

Such programs may also be encoded and transmitted using carrier signals adapted for transmission via wired, optical, and/or wireless networks conforming to a variety of protocols, including the Internet. As such, a computer readable medium may be created using a data signal encoded with such programs. Computer readable media encoded with the program code may be packaged with a compatible device or provided separately from other devices (e.g., via Internet download). Any such computer readable medium may reside on or within a single computer product (e.g., a hard drive, a CD, or an entire computer system), and may be present on or within different computer products within a system or network. A computer system may include a monitor, printer, or other suitable display for providing any of the results mentioned herein to a user.

Any of the methods described herein may be totally or partially performed with a computer system including one or more processors, which can be configured to perform the steps. Any operations performed with a processor (e.g., aligning, determining, comparing, computing, calculating) may be performed in real-time. The term “real-time” may refer to computing operations or processes that are completed within a certain time constraint. The time constraint may be 1 minute, 1 hour, 1 day, or 7 days. Thus, embodiments can be directed to computer systems configured to perform the steps of any of the methods described herein, potentially with different components performing a respective step or a respective group of steps. Although presented as numbered steps, steps of methods herein can be performed at a same time or at different times or in a different order. Additionally, portions of these steps may be used with portions of other steps from other methods. Also, all or portions of a step may be optional. Additionally, any of the steps of any of the methods can be performed with modules, units, circuits, or other means of a system for performing these steps.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom” or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A method comprising:
performing, with a charged particle system having a first milling setting, a first milling operation on a sample at a first time;
generating a first image of the sample based on the first milling operation;
determining, based on the first image, a first set of tracking features of the sample;
performing, with the charged particle system having the first milling setting, a 6 second milling operation on the sample at a second time;
generating a second image of the sample based on the second milling operation; 8
determining, based on the second image, a first change to the first set of tracking 9 features; and
adjusting the first milling setting to a second milling setting based on the first change.

2. The method of claim 1, wherein:
determining the first set of tracking features includes determining a first attribute of the first set of tracking features;
determining the first change includes determining a first attribute change to the first attribute; and
adjusting the first milling setting includes adjusting the first milling setting based on the first attribute change.

3. The method of claim 2, further comprising:
determining that a capping layer of the sample is milled too thin based on the first attribute change; and
adjusting the first milling setting based on the determination that the capping layer is milled too thin.

4. The method of claim 2, wherein the first attribute can include at least one of a position, shape, or size of each tracking feature of the first set of tracking features.

5. The method of claim 2, further comprising:
determining, based on the first image, a second set of tracking features of the sample;
determining, based on the second image, a second change to the second set of tracking features; and
performing a comparison between the first change and the second change, wherein adjusting the first milling setting is based on the comparison.

6. The method of claim 5, further comprising adjusting the first milling setting when the comparison is greater than a predetermined value.

7. The method of claim 6, wherein the predetermined value includes one of a predetermined distance or a predetermined angle.

8. The method of claim 5, wherein:
determining the second set of tracking features includes determining a second attribute of the second set of tracking features;
determining the second change includes determining a second attribute change to the second attribute; and
performing the comparison includes comparing the first attribute change and the second attribute change.

9. The method of claim 8, wherein:
the first attribute change includes a first position change and the second attribute change includes a second position change; and
adjusting the first milling setting includes adjusting the first milling setting based on the first position change and the second position change.

10. The method of claim 8, further comprising determining a first direction based on the first attribute change and a second direction based on the second attribute change, wherein adjusting the first milling setting includes adjusting the first milling setting based on the first direction and the second direction.

11. The method of claim 10, further comprising determining an angle based on the first direction and the second direction, wherein adjusting the first milling setting includes adjusting the first milling setting based on the angle.

12. The method of claim 8, further comprising determining a first rate of deformation based on the first attribute change and a second rate of deformation based on the second attribute change, wherein adjusting the first milling setting includes adjusting the first milling setting based on the first position change and the second position change.

13. The method of claim 1, wherein determining the first set of tracking features includes identifying features of a sample with an artificial intelligence model used for image processing.

14. The method of claim 13, wherein the artificial intelligence model includes a zero-shot foundational model.

15. The method of claim 1, wherein adjusting the first milling setting includes adjusting at least one of a current used to generate an ion beam used to mill the sample, a position of the sample, or a position of the ion beam.

16. The method of claim 1, wherein performing the milling operation at the first time and the second time includes milling a first portion of the sample, and the method further comprising performing, with the charged particle system having the second milling setting, a third milling operation on the sample at a third time at a second portion of the sample different than the first portion.

17. A system, comprising:
one or more computing devices; and
memory storing instructions, the instructions being executable by the one or more computing devices, wherein the one or more computing devices are configured to:
perform, with a charged particle system having a first milling setting, a first milling operation on a sample at a first time;
generate a first image of the sample based on the first milling operation;
determine, based on the first image, a first set of tracking features of the sample;
perform, with the charged particle system having the first milling setting, a second milling operation on the sample at a second time;
generate a second image of the sample based on the second milling operation;
determine, based on the second image, a first change to the first set of tracking features; and
adjust the first milling setting to a second milling setting based on the first change.

18. The system of claim 17, wherein:
determining the first set of tracking features includes determining a first attribute of the first set of tracking features;
determining the first change includes determining a first attribute change to the first attribute; and
adjusting the first milling setting includes adjusting the first milling setting based on the first attribute change.

19. The system of claim 17, wherein determining the first set of tracking features includes identifying features of a sample with artificial intelligence model used for image processing.

20. A non-transitory computing-device readable storage medium on which computing-device readable instructions of a program are stored, the instructions, when executed by one or more computing devices, causing the one or more computing devices to perform a method, comprising:
performing, with a charged particle system having a first milling setting, a first milling operation on a sample at a first time;
generating a first image of the sample based on the first milling operation;
determining, based on the first image, a first set of tracking features of the sample;
performing, with the charged particle system having the first milling setting, a second milling operation on the sample at a second time;
generating a second image of the sample based on the second milling operation;
determining, based on the second image, a first change to the first set of tracking features; and
adjusting the first milling setting to a second milling setting based on the first change.
